(19) United States
(12) Patent Application Publication
(10) Pub. No.: US 2009/0115070 A1
(43) Pub. Date: May 7, 2009

(54) SEMICONDUCTOR DEVICE AND METHOD FOR MANUFACTURING THEREOF

(76) Inventors: Junji TANAKA, Kanagawa (JP); Masahiko Harayama, Kanagawa (JP); Masanori Onodera, Kanagawa (JP)

Correspondence Address: SPANSION LLC C/O MURABITO , HAO & BARNES LLP, TWO NORTH MARKET STREET, THRID FLOOR, SAN JOSE, CA, 95113, US

(21) Appl. No.: 12/258,131

(22) Filed: Oct. 24, 2008

(30) Foreign Application Priority Data
Sep. 20, 2007 (JP) 2007-243952
Oct. 25, 2007 (JP) 2007-277999

(51) Int. Cl. H01L 23/48; H01L 21/60

(52) U.S. Cl. 257/777; 257/784; 438/118; 257/E21.514; 257/E23.01

(57) ABSTRACT

A semiconductor device includes a semiconductor chip 10, a connector terminal 30 electrically coupled with the semiconductor chip 10, a resin section 40 for molding the semiconductor chip 10 and the connector terminal 30 such that a lower surface of the semiconductor chip 10 opposite a surface on which a circuit 12 is formed is exposed, and a first chip 20 formed on the semiconductor chip 10 having an upper surface exposed from the resin section and a thermal expansion coefficient smaller than that of the resin section.

### CLAIM OF PRIORITY

This application claims priority from Japanese patent application 2007-277999 filed on Oct. 25, 2007

### TECHNICAL FIELD

The present invention relates to a semiconductor device and a method for manufacturing thereof, and more particularly, to a semiconductor device having a semiconductor chip sealed with a resin section and a method for manufacturing thereof.

### BACKGROUND ART

A recent trend in the manufacture of semiconductor devices is to create thinner semiconductor devices for realizing higher packaging density. Japanese Unexamined Patent Application Publication Nos. 2003-249604 and 2003-133480 disclose a semiconductor device having the back surface of the semiconductor chip exposed from the resin section.

FIG. 1 is a sectional view of the semiconductor device according to Japanese Unexamined Patent Application Publication No. 2003-249604. A semiconductor chip 10 and a lead 30 are electrically coupled with a bonding wire 32. The semiconductor chip 10 and the bonding wire 32 are sealed with a resin section 40. The semiconductor chip 10 has the back surface (surface opposite the one on which a circuit 12 is formed) exposed from the resin section 40.

According to the semiconductor device disclosed in Japanese Unexamined Patent Application Publication Nos. 2003-249604 and 2003-133480, the back surface of the semiconductor chip is exposed from the resin section, thereby reducing the thickness of the semiconductor device. However, each thermal expansion coefficient of the resin section 40 and the semiconductor chip 10 of the semiconductor device is large, and accordingly, the thinner the semiconductor device becomes, the larger the warping thereof becomes.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

According to one embodiment of the present invention, there is provided a semiconductor device which includes a semiconductor chip, a connector terminal electrically coupled with the semiconductor chip, a resin section for sealing the semiconductor chip and the connector terminal such that a lower surface of the semiconductor chip opposite a surface on which a circuit is formed is exposed, and a first chip formed on the semiconductor chip, having an upper surface exposed from the resin section and a thermal expansion coefficient smaller than that of the resin section.

According to another embodiment of the present invention, there is provided a semiconductor device which includes a semiconductor chip, a connector terminal electrically coupled with the semiconductor chip, a first chip formed on an upper surface of the semiconductor chip, a second chip formed on a lower surface of the semiconductor chip, and a resin section for sealing the semiconductor chip and the connector terminal such that an upper surface of the first chip and a lower surface of the second chip are exposed. Each thermal expansion coefficient of the first chip and the second chip is smaller than that of the resin section.

According to yet another embodiment of the present invention, there is provided a laminated semiconductor device which includes a first semiconductor device and a second semiconductor device each formed as the above semiconductor device.

According to a further embodiment of the present invention, there is provided a method for manufacturing a semiconductor device including the steps of electrically coupling a semiconductor chip and a connector terminal, adhering a first chip to an upper surface of the semiconductor chip, on which a circuit is formed, and forming a resin section having a thermal expansion coefficient larger than that of the first chip for sealing the semiconductor chip, the first chip and the connector terminal such that a lower surface of the semiconductor chip and an upper surface of the first chip are exposed.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a sectional view of a semiconductor device according to a related art;

FIG. 2 is a top view of a semiconductor device according to a first embodiment;

FIG. 3 is a sectional view of the semiconductor device according to the first embodiment;

FIG. 4A is a sectional view showing the formation of a lead frame on an adhesive layer of the semiconductor device according to the first embodiment;

FIG. 4B is a sectional view showing the position of a plurality of semiconductor chips in a semiconductor device according to the first embodiment;

FIG. 4C is a sectional view showing the formation of a circuit in a semiconductor device according to the first embodiment;

FIG. 4D is a sectional view showing an exemplary configuration of a plurality of bonding wires in a semiconductor device according to the first embodiment;

FIG. 5A is a sectional view depicting the formation of a semiconductor chip, a first chip and a lead in a semiconductor device according to the first embodiment;

FIG. 5B is a sectional view depicting the polishing of an upper surface of a semiconductor chip with a resin section in a semiconductor device according to the first embodiment;

FIG. 5C is a sectional view depicting the formation of a semiconductor chip, a first chip and a lead in a semiconductor device according to the first embodiment;

FIG. 6 is a sectional view of a semiconductor device according to a second embodiment;

FIG. 7 is a sectional view a first chip having substantially the same size as a semiconductor chip in a semiconductor device according to a third embodiment;

FIG. 8 is a sectional view a first chip which is larger than a semiconductor chip in a semiconductor device according to a third embodiment;

FIG. 9 is a sectional view of a semiconductor device according to a fourth embodiment;

FIG. 10 is a sectional view of a semiconductor device according to a fifth embodiment;

FIG. 11 is a sectional view depicting the formation of a first chip on an upper surface of a semiconductor chip in a semiconductor device according to a sixth embodiment;

FIG. 12 is a sectional view depicting a first chip having substantially the same size as a semiconductor chip in a semiconductor device according to a sixth embodiment;

FIG. 13 is a sectional view depicting a first chip which is larger than a semiconductor chip in a semiconductor device according to a sixth embodiment;

FIG. 14 is a sectional view depicting a first chip with a cascading structure in a semiconductor device according to a sixth embodiment;

FIG. 15 is a sectional view depicting a semiconductor chip which is flip-chip bonded to a lead in a semiconductor device according to a sixth embodiment;

FIG. 16 is a sectional view of a first chip being formed as a semiconductor chip in a semiconductor device according to a seventh embodiment;

FIG. 17 is a sectional view depicting a first chip which is substantially the same size as a semiconductor chip in a semiconductor device according to a seventh embodiment;

FIG. 18 is a sectional view depicting a first chip which is larger than a semiconductor chip in a semiconductor device according to a seventh embodiment;

FIG. 19 is a sectional view depicting a first chip with a cascading structure in a semiconductor device according to the seventh embodiment;

FIG. 20 is a sectional view depicting a semiconductor chip which is flip-chip bonded to a lead in a semiconductor device according to a seventh embodiment;

FIG. 21 is a sectional view depicting the formation of an alternate first chip on an upper surface of a semiconductor chip in a semiconductor device according to an eighth embodiment;

FIG. is a sectional view depicting an alternate first chip having substantially the same size as a semiconductor chip in a semiconductor device according to an eighth embodiment;

FIG. 23 is a sectional view depicting an alternate first chip which is larger than a semiconductor chip in a semiconductor device according to an eighth embodiment;

FIG. 24 is a sectional view depicting an alternate first chip with a cascading structure in a semiconductor device according to an eighth embodiment;

FIG. 25 is a sectional view depicting a semiconductor chip which is flip-chip bonded to a lead in a semiconductor device with an alternate first chip according to an eighth embodiment;

FIG. 26 is a sectional view of a semiconductor device with an alternate connector terminal according to a ninth embodiment;

FIG. 27 is a sectional view of a semiconductor device with a protruding lead according to a ninth embodiment;

FIG. 28 is a sectional view of a semiconductor device with a bonding wire connected to a solder ball according to a ninth embodiment; and

FIG. 29 is a sectional view of a semiconductor device with a bonding wire entirely molded with an adhesive agent according to a ninth embodiment.

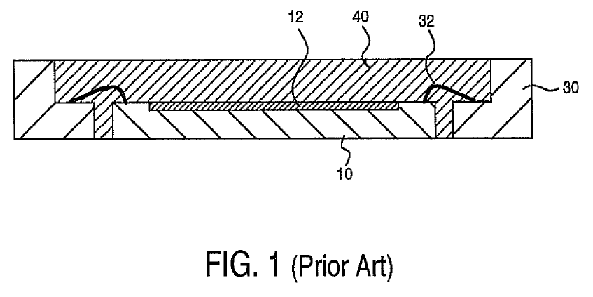

### DETAILED DESCRIPTION

Reference will now be made in detail to the preferred embodiments of the claimed subject matter, a method and system for the use of a reputation service provider, examples of which are illustrated in the accompanying drawings. While the claimed subject matter will be described in conjunction with the preferred embodiments, it will be understood that they are not intended to be limit to these embodiments. On the contrary, the claimed subject matter is intended to cover alternatives, modifications and equivalents, which may be included within the spirit and scope as defined by the appended claims.

Furthermore, in the following detailed descriptions of embodiments of the claimed subject matter, numerous specific details are set forth in order to provide a thorough understanding of the claimed subject matter. However, it will be recognized by one of ordinary skill in the art that the claimed subject matter may be practiced without these specific details. In other instances, well known methods, procedures, components, and circuits have not been described in detail as not to unnecessarily obscure aspects of the claimed subject matter.

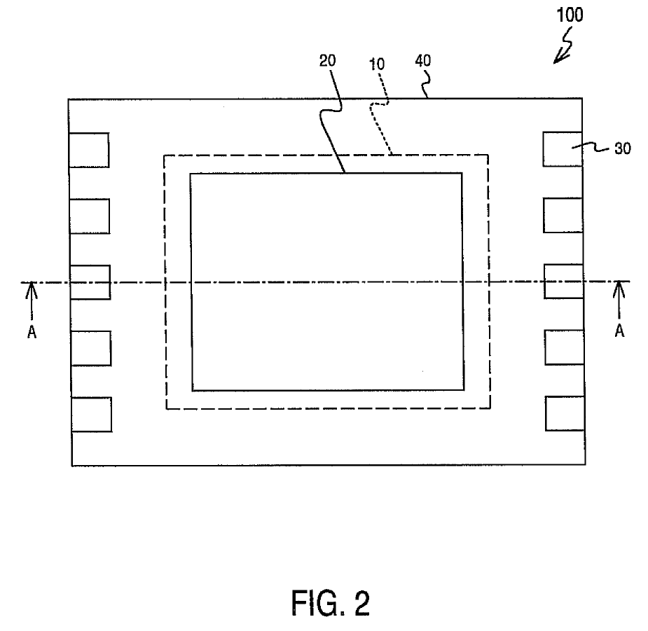

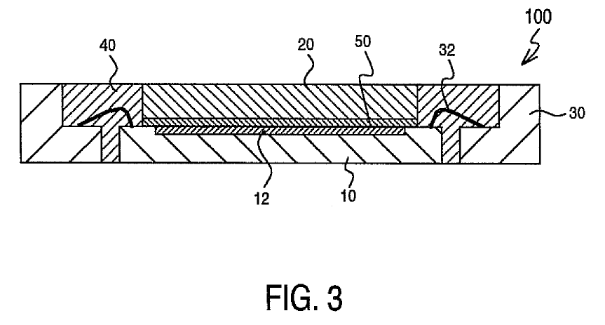

A semiconductor device according to a first embodiment will be described referring to FIGS. 2 and 3. FIG. 2 is a top view of a first embodiment (a semiconductor chip 10 is shown by a broken line through a resin section). FIG. 3 is a sectional view taken along line A-A of FIG. 2. Referring to FIGS. 2 and 3, in a typical semiconductor device 100, a semiconductor chip 10 is formed of silicon and electrically coupled with a lead 30 (implemented as, for example, a connector terminal), and formed of a substance such as Cu and Cu alloy with a bonding wire 32 formed from such metals as Cu, Al or Au. For example, a resin section 40 formed of a thermosetting epoxy resin is employed to mold the semiconductor chip 10, the lead 30 and the bonding wire 32. The lower surface of the semiconductor chip 10 opposite the surface on which a circuit 12 is formed is exposed from the resin section 40. A first chip 20 is applied onto the upper surface of the semiconductor chip 10 via an adhesive agent 50 such as the epoxy resin or the silicon resin. The upper surface of the first chip 20 is exposed from the resin section 40.

In one embodiment, the linear thermal expansion coefficients of the epoxy resin and the silicon may be 9 μK⁻¹ and 3 μK¹, respectively. Generally, the expansion coefficient of the resin is larger than that of the semiconductor. So a material with the thermal expansion coefficient smaller than that of the resin section 40 is selected as the one for forming the first chip 20. That is, the resin section 40 has a thermal expansion coefficient larger than that of the first chip 20. For example, the linear thermal expansion coefficient of 42 alloy (alloy of 42 wt.% of Ni and Fe) is 4.6 μK⁻¹. So in one embodiment, 42 alloy may be selected as the first chip 20. Due to the reduction in the difference between the upper and the lower thermal stress values, warping of the semiconductor device 100 under the thermal stress may be suppressed.

In some embodiments, the linear thermal expansion coefficient of the resin in the resin section of the semiconductor device is generally larger than 9 μK⁻¹. Accordingly, the linear thermal expansion coefficient of the first chip 20 is preferably set to the value equal to or smaller than 9 μK⁻¹, and more preferably, 8 μK⁻¹. The linear thermal expansion coefficient of the silicon used to form the semiconductor chip 10 is approximately 3 μK⁻¹. Preferably, the linear thermal expansion coefficient of the first chip 20 is equal to or larger than 3 μK⁻¹.

In alternate embodiments, any material may be employed for forming the first chip 20 so long as it exhibits the thermal expansion coefficient smaller than that of the resin section 40. However, it may be preferable to use the material for forming the first chip 20, which is the same as the one for forming the semiconductor chip 10. For example, silicon may be employed for forming both the semiconductor chip 10 and the first chip 20. This makes it possible to allow the distribution of the thermal stress symmetrically, with respect to the upper and the lower portions, thus further suppressing warping of the semiconductor device 100.

Generally, the thermal resistivity of the metal or the semiconductor is lower than that of the resin. As the same metal of the semiconductor is used for forming the first chip 20, the thermal resistivity of the first chip 20 may also be lower than that of the resin section 40. The upper surface of the first chip 20 and the lower surface of the semiconductor chip 10 are exposed from the resin section 40. Accordingly, the heat generated in the circuit 12 of the semiconductor chip 10 is released to the lower surface and the upper surface of the semiconductor device via the semiconductor chip 10 and the first chip 20.

The resin section 40 may contain the element which irradiates a ray therein. If the resin section 40 is formed on the circuit 12 of the semiconductor chip 10 as disclosed in Japanese Unexamined Patent Application Publication Nos. 2003-249604 and 2003-133480, the a ray radiated from the resin section 40 may cause a malfunction of the circuit 12. On the contrary, in the first embodiment, silicon is used for forming the first chip 20, the incident a ray to the circuit 12 of the semiconductor chip 10 may be suppressed for the purposes of preventing malfunction of the circuit 12. I To prevent malfunction of the circuit 12, it is preferable that the surface of the circuit 12 is entirely covered with the first chip 20.

In the first embodiment, it may be preferable to apply the adhesive agent 50 between the semiconductor chip 10 and the first chip 20. This makes it possible to prevent the direct contact between the semiconductor chip 10 and the first chip 20. The use of the adhesive agent 50 formed of the resin allows the elasticity thereof to be smaller than each elasticity of the semiconductor chip 10 and the first chip 20, respectively. Accordingly, warping of the semiconductor device 100 resulting from the thermal expansion coefficient of the adhesive agent 50 may be reduced.

Preferably, the resin section 40 includes the filler so as to ensure its strength, and the adhesive agent 50 is filler-free so as to be thin and exhibit lower elasticity. In some embodiments, It may be preferable to expose the side surface of the lead 30 from the resin section 40. This makes it possible to make the semiconductor device 100 compact.

In still further embodiments, thickness of the semiconductor chip 10 and the first chip 20 may be preferably set to 50 μm and 100 μm, respectively. The resulting thickness of the semiconductor device 100 may be set to the value ranging from 150 μm to 200 μm.

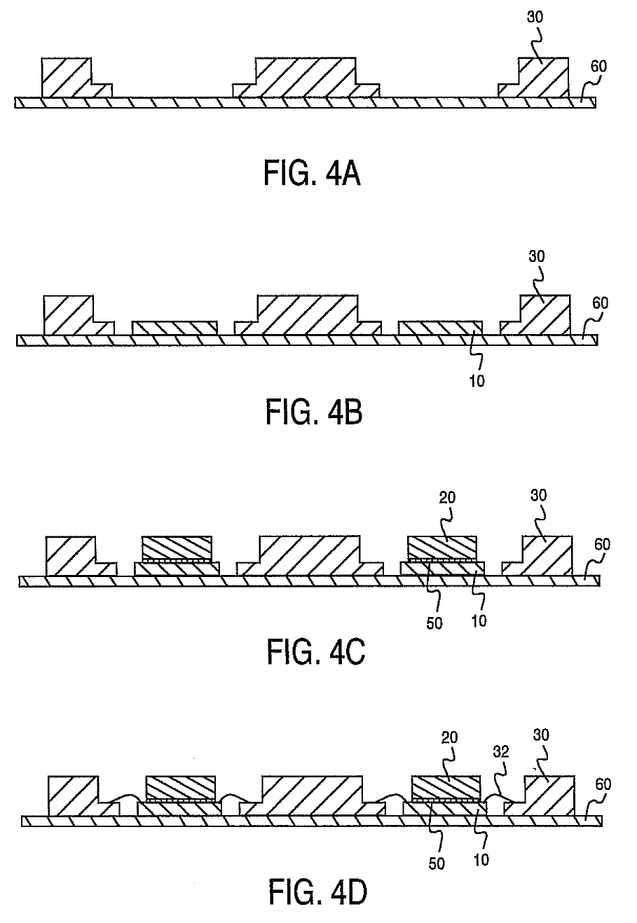

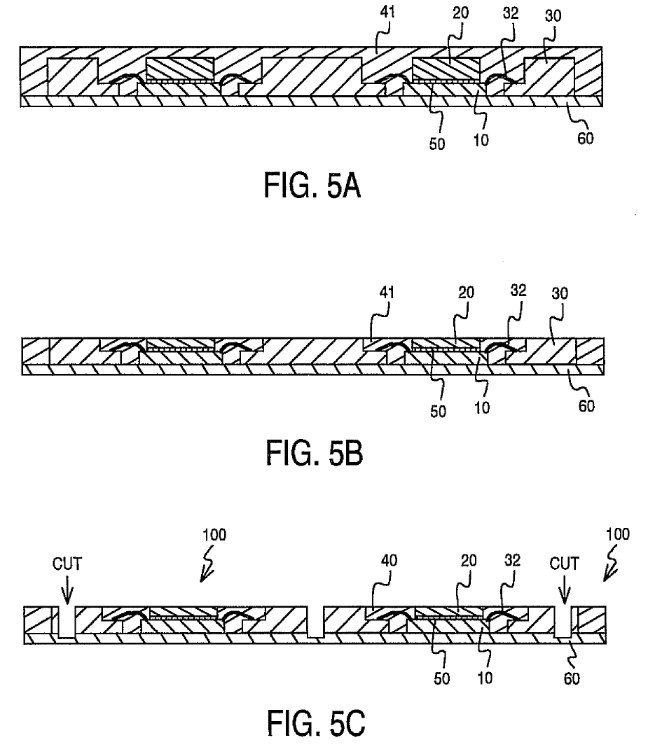

A method for manufacturing the semiconductor device 100 according to the first embodiment will be described referring to FIGS. 4A to 5C. Referring to FIG. 4A, a lead frame to be formed as the lead 30 is applied on an adhesive layer (not shown, but formed on an upper surface of a film 60) of the film 60. Referring to FIG. 4B, the plurality of semiconductor chips 10 is disposed on the adhesive layer of the film 60 such that each surface on which the circuit is formed is directed upward. The first chip 20 is adhered to the upper surface of the semiconductor chip 10 using the adhesive agent 50 formed of the resin. A pad (not shown) formed on the upper surface of the semiconductor chip 10 and the lead 30 are electrically coupled using the bonding wire 32.

Referring to FIG. 5A, a resin 41, for example, thermosetting epoxy resin is formed to mold the semiconductor chip 10, the first chip 20, the lead 30 and the bonding wire 32. Referring to FIG. 5B, the resin 41 is polished to form the resin section 40 such that the respective upper surfaces of the first chip 20 and the lead 30 are exposed. Referring to FIG. 5C, the lead 30 and the resin section 40 are cut to the intermediate depth of the film 60 using the diamond wheel so as to separate the individual semiconductor device 100 on the film 60. The semiconductor device 100 according to a first embodiment, is thus produced.

In the first embodiment, the semiconductor chip 10 and the lead 30 are formed on the film 60 as shown in FIGS. 4A and 4B. Then the resin 41 is formed to mold the semiconductor chip 10, the first chip 20 and the lead 30 as shown in FIG. 5A. The resin 41 is polished to expose the upper surface of the first chip 20 as shown in FIG. 5B to form the resin section 40. Accordingly, when the first chip 20 is adhered onto the semiconductor chip 10, damage of the thick first chip 20 may be prevented during handling thereof. As the upper surface of the first chip 20 is polished, the resultant semiconductor device 100 may be formed into the thin structure.

The first chip 20 is applied on the film 60 shown in FIG. 4B, and the semiconductor chip 10 is adhered onto the upper surface of the first chip 20 such that the surface on which the circuit is formed is directed downward as shown in FIG. 4C. FIG. 4D depicts the semiconductor device of FIG. 4C with bonding wires 32 in an exemplary configuration. FIG. 5B, the upper surface (opposite the surface on which the circuit is formed) of the semiconductor chip 10 may be polished together with the resin section 40 so as to form the modified example of the first embodiment. The semiconductor chip 10, thus, may be further thinned.

The two-dimensional bar code may be imprinted on the portion of the first chip 20 exposed from the resin section 40 using the laser light ray. Unlike where the imprint is performed on the resin section 40, this may further improve the visibility. When the imprint is performed on the resin section 40, the laser light ray may cause damage to the circuit 12 of the semiconductor chip 10. In the first embodiment, the damage to the circuit 12 may be suppressed by the first chip 20.

### SECOND EMBODIMENT

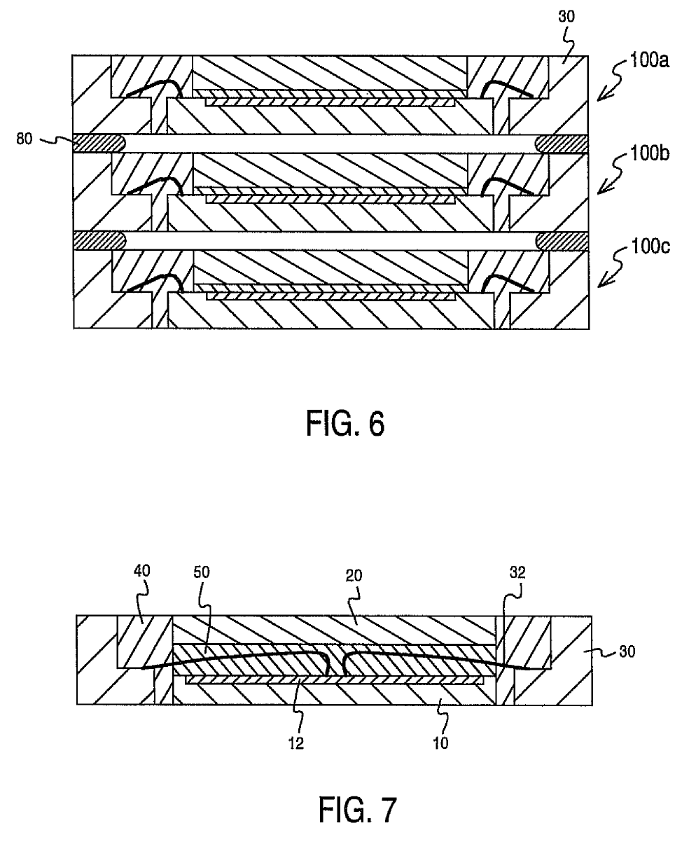

A second embodiment is an embodiment of a laminated semiconductor device formed by laminating the semiconductor devices 100 according to the first embodiment. Referring to FIG. 6, semiconductor devices 100a to 100c according to the first embodiment are laminated. First semiconductor device 100a is a higher positioned laminated semiconductor device, and second semiconductor device 100b is a lower positioned laminated semiconductor device. The lower surface of the lead 30 (used, for example, as a connector terminal of the first semiconductor device 100a) is connected to the upper surface of the lead 30 of the second semiconductor device 100b with a solder 80. The semiconductor device 100 according to the first embodiment has upper and lower surfaces of the lead 30 exposed from the resin section 40 so as to allow easy lamination of the semiconductor devices 100. The semiconductor chip 10 of the first semiconductor device 100a is disposed above the first chip 20 of the second semiconductor device 100b. This allows the semiconductor chip 10 and the first chip 20 to efficiently radiate the heat generated in the circuit. It is preferable to apply the adhesive agent between the first chip 20 of the second semiconductor device 100b and the semiconductor chip 10 of the first semiconductor device 100a. This makes it possible to improve the radiation performance.

### THIRD EMBODIMENT

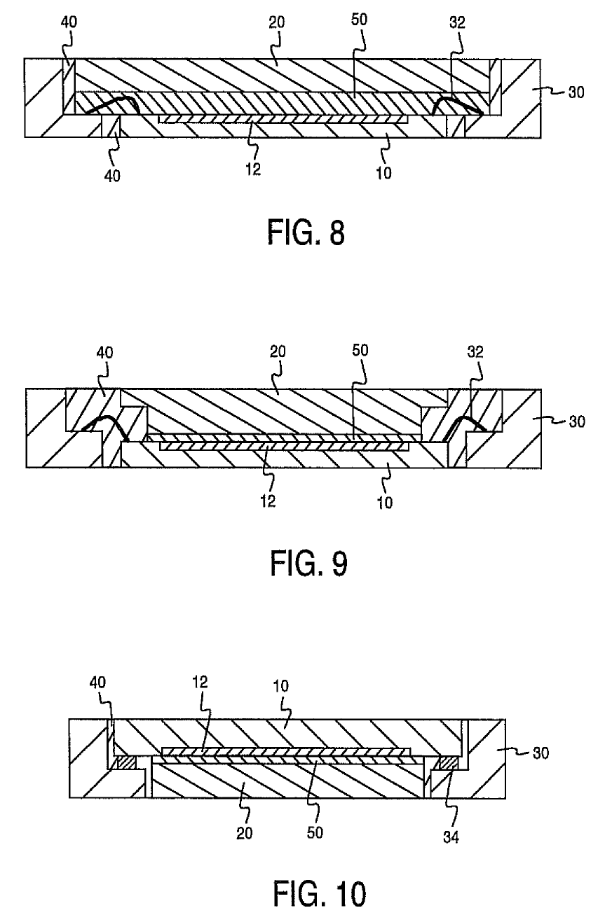

A third embodiment is an embodiment where the bonding wire is molded with the adhesive agent. Referring to FIGS. 7 and 8, the semiconductor device according to the third embodiment has the bonding wire 32 molded with the adhesive agent 50. As shown in FIG. 7, this makes it possible to allow the first chip 20 to have substantially the same size as that of the semiconductor chip 10, thus making the semiconductor chip 10 and the first chip 20 symmetrically arranged and further suppressing warping of the semiconductor device. The bonding wire 32 may be connected to the pad around the center of the semiconductor chip 10.

Referring to FIG. 8, the first chip 20 may be larger than that of the semiconductor chip 10. This makes it possible to dispose the first chip 20 on the bonding wire 32. There may be a case where it is not preferable to have the bonding wire 32 viewable through the top surface of the resin section 40, with respect to the outer appearance. In the aforementioned case, the resin section 40 may be thickened. As shown in FIG. 8, the first chip 20 on the bonding wire 32 serves to prevent the bonding wire 32 from being viewable through the resin section, resulting in an even thinner semiconductor device.

### FOURTH EMBODIMENT

A fourth embodiment is an embodiment where the first chip 20 has a cascading portion. Referring to FIG. 9, in the semiconductor device according to the fourth embodiment, the first chip 20 has a cascading portion including a small lower portion and a large upper portion. As the lower portion of the first chip 20 is small, the bonding wire 32 may be connected to the semiconductor chip 10 with the thin adhesive agent 50. The large upper portion allows the first chip 20 to have substantially the same as the semiconductor chip 10, thus suppressing warping of the semiconductor device.

### FIFTH EMBODIMENT

A fifth embodiment is an embodiment where the semiconductor chip 10 is flip-chip bonded to the lead 30. Referring to FIG. 10, the semiconductor chip 10 is flip-chip bonded to the lead 30 using a metal bump 34 formed of, for example, solder substance or Au. The first chip 20 is adhered onto the upper surface (the lower surface shown in FIG. 10, on which the circuit 12 is formed) of the semiconductor chip 10 using the adhesive agent 50. According to the fifth embodiment, the metal bump 34 may be used for bonding the semiconductor chip 10 and the lead 30.

### SIXTH EMBODIMENT

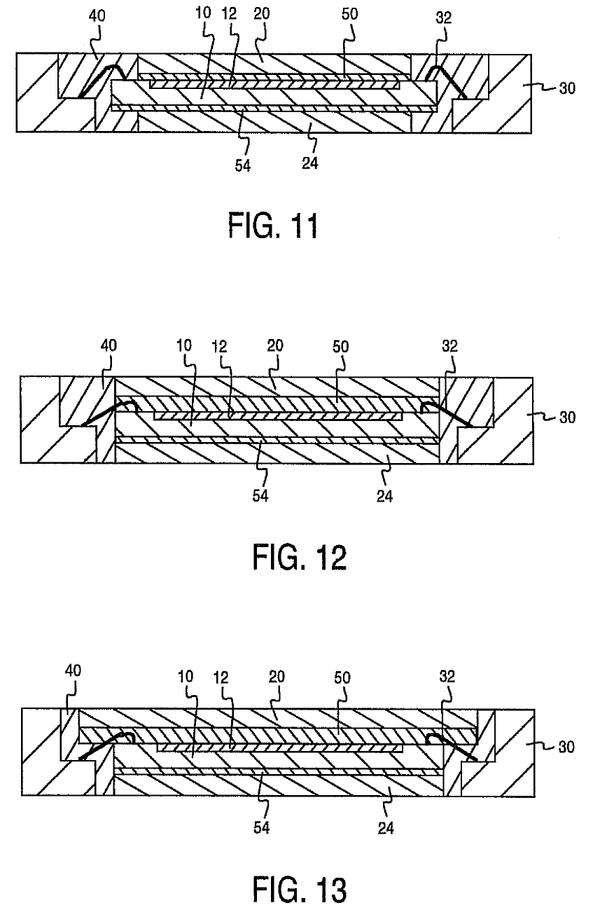

A sixth embodiment is an embodiment where the first chip and the second chip are disposed above and below the semiconductor chip. Referring to FIG. 11, the first chip 20 is formed on the upper surface of the semiconductor chip 10, and a second chip 24 is formed on the lower surface of the semiconductor chip 10. The resin section 40 molds the semiconductor chip 10, the first chip 20, the second chip 24, the lead 30 and the bonding wire 32. The upper surface of the first chip 20 and the lower surface of the second chip 24 are exposed from the resin section 40. As described in previous embodiments, each thermal expansion coefficient of the first chip 20 and the second chip 24 may be smaller than that of the resin section 40.

In the sixth embodiment, the first chip 20 and the second chip 24—each having a smaller thermal expansion coefficient than that of the resin section 40—are symmetrically arranged to interpose the semiconductor chip 10 so as to suppress warping of the semiconductor device under the thermal stress. Especially when each of the first chip 20 and the second chip 24 is formed of a material different from the one used to form the semiconductor chip 10, warping of the semiconductor device may further be suppressed. According to the first embodiment, the semiconductor chip 10 may be damaged because of the exposed lower surface. However, according to the sixth embodiment, the lower surface of the semiconductor chip 10 is molded with the second chip 24, thus preventing damage to the semiconductor chip 10.

Referring to FIGS. 12 and 13, the adhesive agent 50 may be applied so as to partially mold the bonding wire 32. This allows the first chip 20 to have the same size as that of the semiconductor chip 10 as shown in FIG. 12. Alternatively, the first chip 20 may be made larger than the semiconductor chip 10 as shown in FIG. 13.

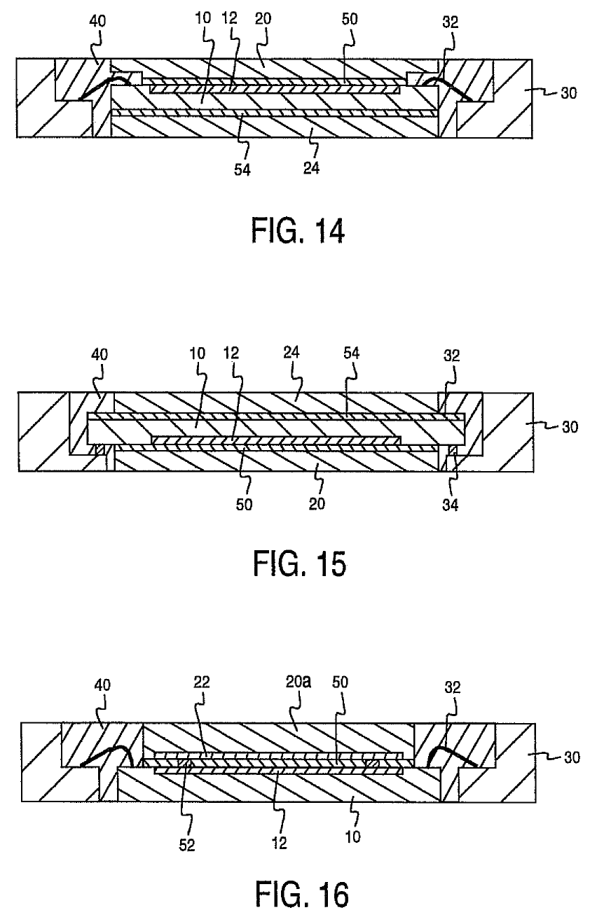

Referring to FIG. 14, in one embodiment the first chip 20 may be formed to have a cascading portion including a small lower portion and a large upper portion. Referring to FIG. 15, the semiconductor chip 10 may be flip-chip bonded to the lead 30 using the metal bump 34.

### SEVENTH EMBODIMENT

A seventh embodiment is an embodiment where the first chip is formed as a semiconductor chip. Referring to FIG. 16, a first chip 20a is formed as a semiconductor chip, and includes a lower surface upon which a circuit 22 is formed. The lower surface of the first chip 20a, on which the circuit 22 is formed, and the upper surface of the semiconductor chip 10, on which the circuit 12 is formed are flip-chip bonded using a metal bump 52. This may electrically couple the circuit 22 of the first chip 20a with the semiconductor chip 10.

The first chip 20a may be formed as the semiconductor chip, thus forming a so-called MCP (Multi Chip Package) to enhance the packaging density of the semiconductor chip.

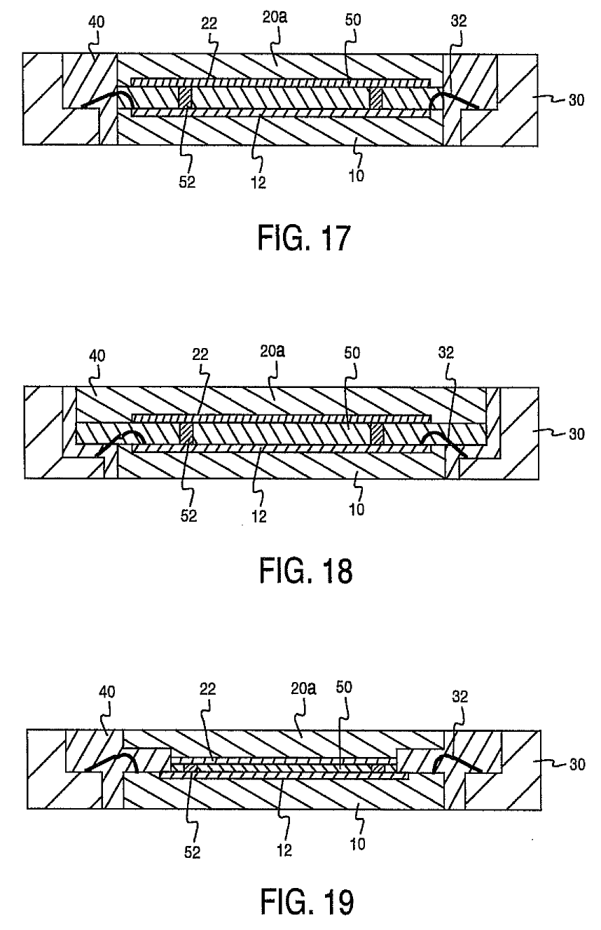

Referring to FIGS. 17 and 18, the adhesive agent is capable of partially molding the bonding wire 32, thus allowing the first chip 20a to have the same size as that of the semiconductor chip 10 as shown in FIG. 17. The first chip 20a may be made larger than the semiconductor chip 10 as shown in FIG. 18.

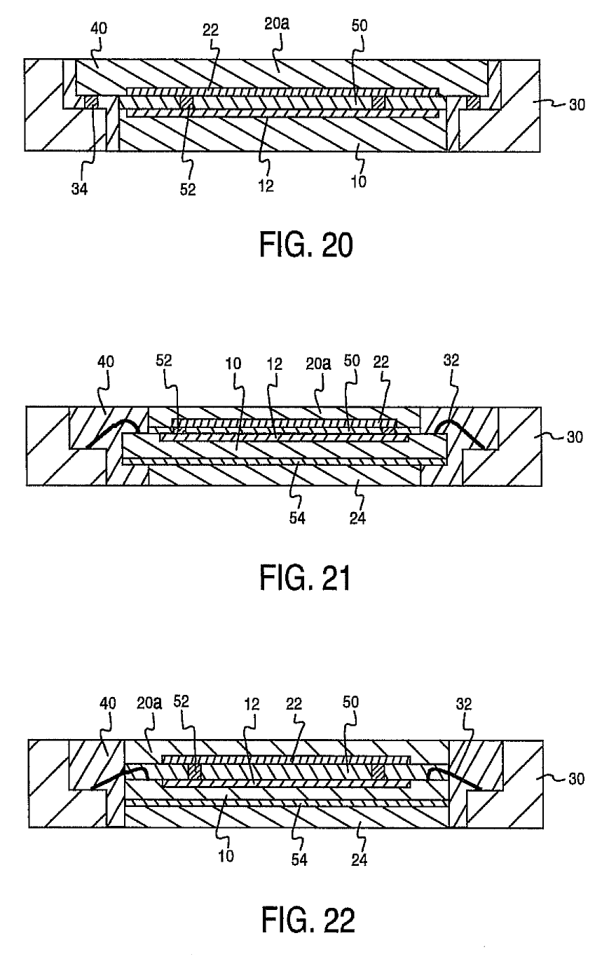

Referring to FIG. 19, the first chip 20a may be formed to have a stepped portion including a small lower portion and a large upper portion. Referring to FIG. 20, the semiconductor chip 10 may be flip-chip bonded to the lead 30 using the metal bump 34.

### EIGHTH EMBODIMENT

An eighth embodiment is an embodiment where the first chip 20a and the second chip 24 are disposed above and below the semiconductor chip 10, respectively. Referring to FIG. 21, the first chip 20a is a semiconductor chip, which is flip-chip bonded to the semiconductor chip 10. The second chip 24 is disposed below the semiconductor chip 10. Referring to FIG. 21, the first chip 20 according to the sixth embodiment shown in FIG. 11 may be replaced by the first chip 20a as the semiconductor is chip flip-chip bonded to the semiconductor chip 10.

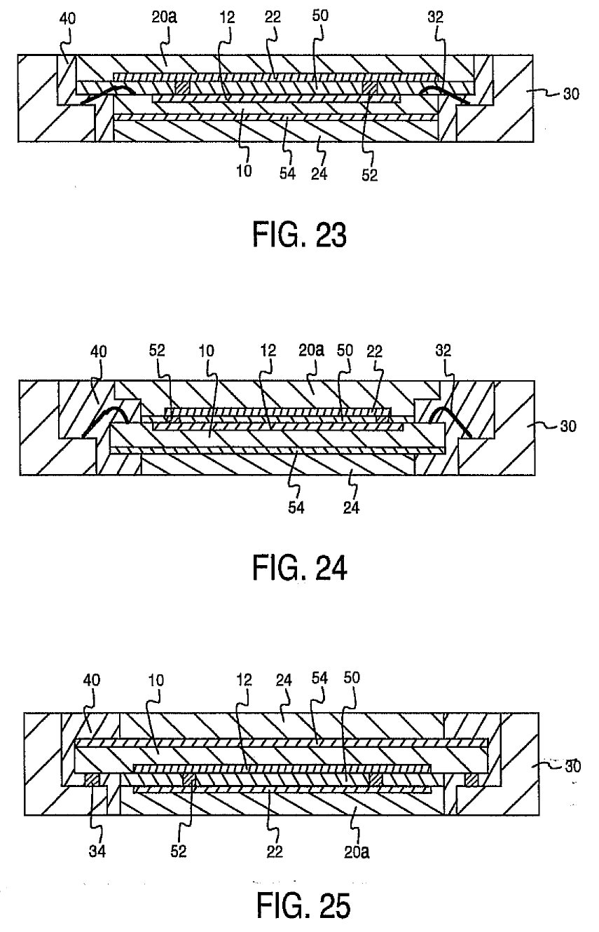

As described above, the first chip 20 according to the sixth embodiment shown in FIGS. 12 to 15 may be replaced by the first chip 20a as shown in FIGS. 22 to 25.

### NINTH EMBODIMENT

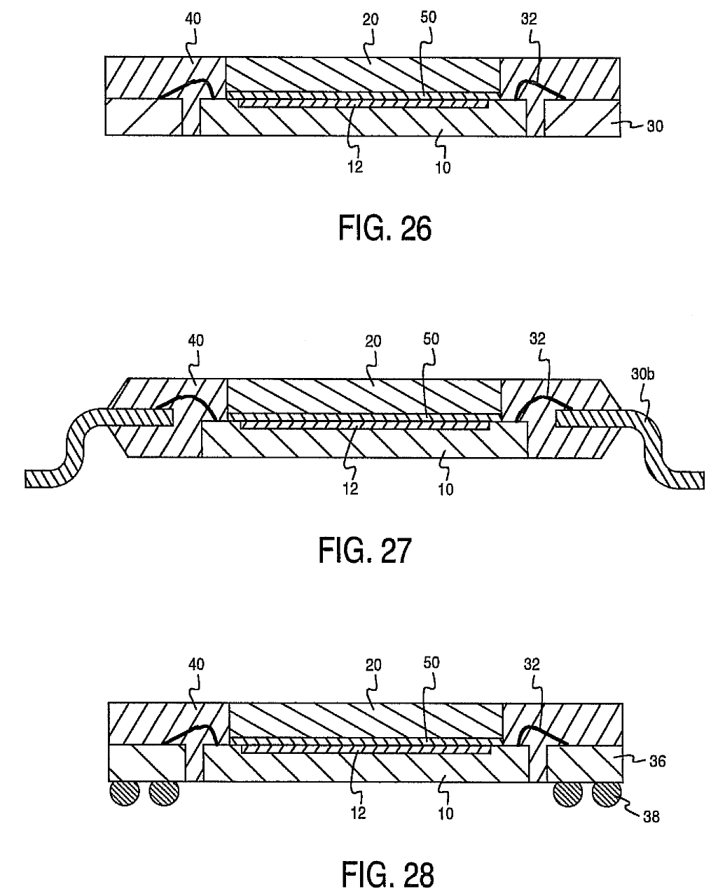

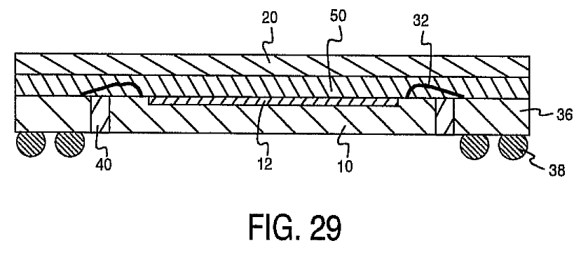

A ninth embodiment is an embodiment where the connector terminal is different from the one described in the first to the eighth embodiments. Referring to FIG. 26, the upper surface of a lead 30 serving as the connector terminal does not have to be exposed from the resin section 40. In this way, the present invention may be applied to quad flat non-leaded package (QFN). Alternatively, the lead 30b may protrude from the resin section 40, as shown in FIG. 27. Accordingly, the present invention may be applied to quad flat packages or thin small outline packages (TSOP). Referring to FIG. 28, the bonding wire 32 may be connected to a solder ball 38 as the connector terminal via a wiring substrate 36. Referring to FIG. 29, the bonding wire 32 may be entirely molded with the adhesive agent 50. Alternatively, the first chip 20 may be employed for covering the entire upper surface of the semiconductor device. As a result, any terminal may be employed as the connector terminal so long as the semiconductor chip 10 is electrically coupled with the region outside the semiconductor device.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A semiconductor device comprising:
a semiconductor chip;
a connector terminal electrically coupled with the semiconductor chip;
a resin section for molding the semiconductor chip and the connector terminal such that a lower surface of the semiconductor chip opposite to a surface on which a circuit is formed is exposed; and
a first chip formed on the semiconductor chip, the first chip having an upper surface exposed from the resin section and a thermal expansion coefficient smaller than that of the resin section.

2. The semiconductor device according to claim 1, wherein an upper surface and a lower surface of the connector terminal are exposed from the resin section.

3. The semiconductor device according to claim 1, wherein the first chip is formed of a same material as that used to form the semiconductor chip.

4. The semiconductor device according to claim 3, wherein a circuit electrically coupled with the semiconductor chip is formed on a lower surface of the first chip.

5. The semiconductor device according to claim 1, further comprising
an adhesive agent applied between the semiconductor chip and the first chip, the adhesive agent molding a bonding wire which bonds the semiconductor chip and the connector terminal.

6. A semiconductor device comprising:
a semiconductor chip;
a connector terminal electrically coupled with the semiconductor chip;
a first chip formed on an upper surface of the semiconductor chip;
a second chip formed on a lower surface of the semiconductor chip; and
a resin section for molding the semiconductor chip and the connector terminal such that an upper surface of the first chip and a lower surface of the second chip are exposed, wherein
a thermal expansion coefficient of the first chip and a thermal expansion coefficient second chip are smaller than that of the resin section.

7. The semiconductor device according to claim 6, wherein an upper surface and a lower surface of the connector terminal are exposed from the resin section.

8. The semiconductor device according to claim 6, wherein the first chip is formed of a same material as that used to form the semiconductor chip.

9. A laminated semiconductor device comprising:
a first semiconductor device; and
a second semiconductor device, wherein the first semiconductor device and the second semiconductor device are laminated such that a lower surface of a connector terminal of the first semiconductor device is connected with an upper surface of a connector terminal of the second semiconductor device.

10. A method for manufacturing a semiconductor device comprising:
electrically coupling a semiconductor chip and a connector terminal;
adhering a first chip to an upper surface of the semiconductor chip, on which a circuit is formed; and
forming a resin section having a thermal expansion coefficient larger than that of the first chip for molding the semiconductor chip, the first chip and the connector terminal such that a lower surface of the semiconductor chip and an upper surface of the first chip are exposed.
